(19) United States
(12) Patent Application Publication
(10) Pub. No.: US 2024/0293912 A1
(43) Pub. Date: Sep. 5, 2024

(54) MANUFACTURING METHOD FOR MANUFACTURING SUBSTRATE OF NITRIDE CRYSTAL OF GROUP 13 ELEMENT IN PERIODIC TABLE

(71) Applicant: KYOCERA Corporation, Kyoto-shi, Kyoto (JP)

(72) Inventors: Mari YOSHIMORI HIGUCHI, Echi-gun, Shiga (JP); Yuri ONO, Higashiomi-shi, Shiga (JP)

(21) Appl. No.: 18/574,699

(22) PCT Filed: Jun. 29, 2022
(86) PCT No.: PCT/JP2022/026095

§ 371 Date: Dec. 27, 2023

(30) Foreign Application Priority Data
Jun. 30, 2021 (JP) 2021-109059

(51) Int. Cl. B24B 37/32; B24B 37/04; C30B 29/40; C30B 33/10; H01L 21/02

(52) U.S. Cl. CPC B24B 37/32; B24B 37/044; C30B 29/406; C30B 33/10; H01L 21/02013

(57) ABSTRACT

A manufacturing method of the present disclosure includes grinding at least one main surface of a crystal of a nitride of a group 13 element while housing the crystal in an opening portion provided in a plate-like carrier, and chemical mechanical polishing (CMP) the main surface ground while the substrate is housed in the carrier. The main surface is a semipolar plane, a nonpolar plane, or an N-face, a slurry used in the CMP is alkaline, and the carrier is made of carbon fiber reinforced plastic.

### TECHNICAL FIELD

The present disclosure relates to a manufacturing method for manufacturing substrates of nitride crystals of group 13 elements in the periodic table such as substrates of gallium nitride (GaN) single crystals.

### BACKGROUND OF INVENTION

Nitride crystals of group 13 elements in the periodic table (hereinafter may be simply referred to as nitride crystals of group 13 elements) represented by gallium nitride (GaN) have excellent semiconductor properties such as a band gap and a dielectric breakdown field. Therefore, they are useful substances for light-emitting devices such as light emitting diodes and laser diodes, and high-frequency and high-power electronic devices.

Nitride crystals of group 13 elements have a hexagonal crystalline structure and have polarity in a c-axis direction. Gallium nitride single crystals having a polar plane (c-plane) as a main surface have been used for gallium nitride-based light emitting diodes (LEDs). However, it has been pointed out that an internal electric field caused by polarity separates electrons and holes, resulting in a decrease in light emission efficiency (droop phenomenon). Therefore, development of devices such as LEDs using gallium nitride crystals having a semipolar plane or a nonpolar plane as a main surface is underway.

Gallium nitride single crystals are also anisotropic in machinability due to a polarity thereof, and the workability differs between a Ga-face and an N-face of a c-plane gallium nitride crystal.

Machining of gallium nitride single crystals mainly includes grinding and chemical mechanical polishing (hereinafter referred to as CMP) (polishing). Patent Documents 1 and 2 describe grinding of a gallium nitride single-crystal substrate.

Patent Document 3 describes that in a c-plane gallium nitride single-crystal substrate, the N-face is polished with alkaline CMP slurry, while the Ga-face is polished with acidic CMP slurry. Patent Document 3 describes lapping or polishing a substrate mounted on a template having a recessed portion or a flat template.

### CITATION LIST

### Patent Literature

Patent Document 1: JP 2013-211491 A
Patent Document 2: JP 2013-229586 A
Patent Document 3: JP 2009-164634 A

### SUMMARY

A manufacturing method for manufacturing a substrate of a crystal of a nitride of a group 13 element according to the present disclosure includes grinding at least one main surface of the crystal of the nitride of a group 13 element while housing the crystal in an opening portion provided in a plate-like carrier, and chemical mechanical polishing the main surface ground while a substrate is housed in the carrier. The main surface is a semipolar plane, a nonpolar plane, or an N-face, the slurry used in the chemical mechanical polishing is alkaline, and the carrier is made of carbon fiber reinforced plastic (CFRP).

### BRIEF DESCRIPTION OF THE DRAWINGS

FIG. 1 is a flowchart illustrating a procedure of a manufacturing method for manufacturing substrates of nitride crystals of group 13 elements according to an embodiment of the present disclosure.

FIG. 2A is a schematic diagram for explaining a polar plane of a gallium nitride single crystal, which is a nitride crystal of a group 13 element.

FIG. 2B is a schematic diagram for explaining a semipolar plane of the gallium nitride single crystal, which is the nitride crystal of a group 13 element.

FIG. 2C is a schematic diagram for explaining a nonpolar plane of the gallium nitride single crystal, which is the nitride crystal of a group 13 element.

FIGS. 3A and 3B are schematic diagrams illustrating a grinding step of grinding gallium nitride single crystals.

FIG. 4 is a plan view illustrating an example of a carrier according to the present disclosure.

FIG. 5A is a plan view schematically illustrating a positional relationship between a single-crystal holder and a wheel-shaped grindstone holder in a front surface grinding step.

FIG. 5B is a partial side view of FIG. 5A.

FIG. 6 is an explanatory diagram illustrating a relationship between a gap between adjacent gallium nitride single crystals and a track width of a grindstone in the grinding step.

FIG. 7A is an explanatory diagram illustrating a relationship between a gallium nitride single crystal and grindstone tracks in the grinding step.

FIG. 7B is an enlarged view of a portion A in FIG. 7A.

FIG. 8A is an explanatory diagram illustrating a relationship between a gallium nitride single crystal and grindstone tracks in the grinding step.

FIG. 8B is an enlarged view of a portion A′ in FIG. 8A.

FIG. 9A is a schematic cross-sectional view of a portion C1 illustrating a grindstone track including a portion b1 and a portion b2 in FIG. 8B.

FIG. 9B is a schematic cross-sectional view of a portion C2 illustrating a grindstone track 8′ in FIG. 8B.

FIG. 10 is an explanatory diagram illustrating an example of an attachment state of multiple gallium nitride single crystals.

FIG. 11 is a schematic diagram for explaining a definition of angle ranges to be ground in the front surface grinding step.

FIG. 12 is an explanatory diagram illustrating angle ranges A to F to be ground in the front surface grinding step.

FIG. 13 is a schematic diagram illustrating a CMP step for the gallium nitride single crystals.

FIG. 14 is a graph illustrating a thickness difference between a carrier and a single crystal after polishing in the CMP step.

FIG. 15A is an explanatory diagram for explaining surface sagging of a single crystal during polishing in the CMP step.

FIG. 15B1 is an explanatory diagram for explaining surface sagging of a single crystal during polishing in the CMP step.

FIG. 15B2 is an explanatory diagram for explaining surface sagging of a single crystal during polishing in the CMP step.

FIG. 15C1 is an explanatory diagram for explaining surface sagging of a single crystal during polishing in the CMP step.

FIG. 15C2 is an explanatory diagram for explaining surface sagging of a single crystal during polishing in the CMP step.

FIG. 16A is a plan view illustrating a carrier.

FIG. 16B is an enlarged view of a portion M in FIG. 16A.

### DESCRIPTION OF EMBODIMENTS

In the following, a manufacturing method for manufacturing substrates of nitride single crystals of group 13 elements of the present disclosure will be described with reference to the accompanying drawings.

Here, the substrate of the nitride crystal of a group 13 element means a substrate made of a nitride crystal of a group 13 element. The substrate has a plate-like shape, that is, a shape having a relatively small thickness with respect to a width or a depth thereof (e.g., 1/10 or less of the width or the depth). The nitride crystal of a group 13 element is represented by, for example, GaₓAl_{y}In_{1-x-y}N (where 0≤x≤1 and 0≤y≤1), and specific examples thereof include gallium nitride, aluminum nitride, indium nitride, or mixed crystals thereof. In this specification, “main surfaces” of a nitride crystal of a group 13 element refer to two surfaces present in the crystal that are spaced apart in a thickness direction (a direction of the smallest crystal dimension), which are a front surface (e.g., a device forming surface) and a back surface.

In the following description, a manufacturing method for manufacturing a gallium nitride single-crystal substrate will be described as a representative example, but other substrates of nitride crystals of a group 13 elements can be manufactured in the same and/or similar manner.

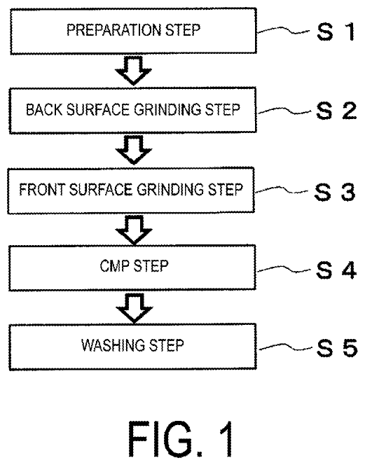

FIG. 1 is a flowchart illustrating an outline of a manufacturing method for manufacturing gallium nitride single-crystal substrates according to an embodiment of the present disclosure.

### Preparation Step S1

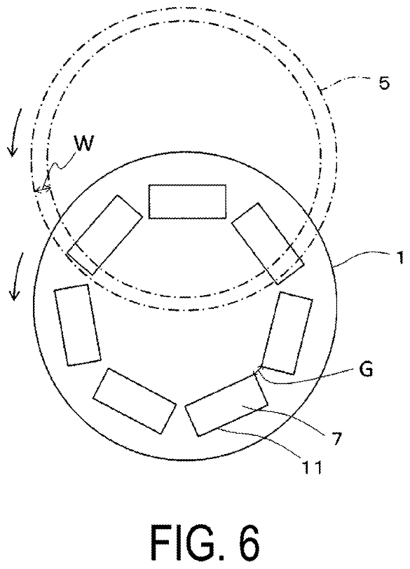

As illustrated in FIG. 1, in a preparation step S1, plate-like gallium nitride single crystals 7 (see, for example, FIG. 6; hereinafter sometimes abbreviated as single crystals 7) are prepared. For example, by a slicing step of slicing an ingot of a gallium nitride single crystal produced by a vapor phase growth method with, for example, a wire saw or the like, plate-like gallium nitride single crystals 7 having main surfaces in a specific orientation can be obtained. Before or after the slicing step, a profile machining step for machining a profile of the single crystal 7 into a desired shape may be performed.

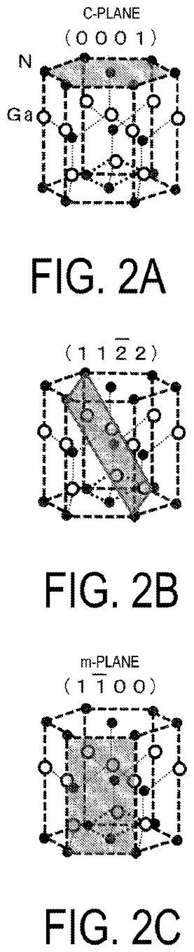

In the present disclosure, the gallium nitride single crystal 7 having a semipolar plane, a nonpolar plane, or an N-face (nitrogen face) as the main surface is used. FIGS. 2A to 2C illustrate a polar plane, a semipolar plane, and a nonpolar plane of the gallium nitride single crystal 7, respectively.

In the gallium nitride single crystal 7, a single crystal having a polar plane (c-plane, {0001} plane illustrated in FIG. 2A) as a main surface is a commonly used plane because the growth technique is well established. On the other hand, a plane perpendicular to the polar plane is a nonpolar plane, such as an m-plane ({1-100} plane) illustrated in FIG. 2C. Planes between polar planes and nonpolar planes, such as a {11-22} plane illustrated in FIG. 2B, a {11-21} plane, a {11-23} plane, a {30-31} plane, a {20-21} plane, a {10-11} plane, and a {10-12} plain are semipolar planes. Substrates of gallium nitride single crystals having a semipolar or nonpolar plane as a main surface are expected to be applied to high-efficiency and high-power light emitting elements.

In the notation of the Miller indices, ( ) represents a specific plane, { } represents an equivalent plane, [ ] represents a specific direction, and < > represents an equivalent direction. Note that orientations having negative numbers are commonly represented by adding a bar above the number, but are represented by a minus (−) for convenience in this specification. For example, the {0001} plane includes a (0001) plane and a (000-1) plane. The {20-21} plane includes a (20-21) plane, a (20-2-1) plane, and planes equivalent thereto.

In the slicing step, for example, by slicing a c-plane-grown gallium nitride single crystal obliquely to the c-plane (so that the main surface is inclined from both the polar plane and the nonpolar plane), a plate-like gallium nitride single crystal 7 having a semipolar plane as the main surface can be cut out. On the other hand, by slicing perpendicular to the c-plane, a plate-like gallium nitride single crystal 7 having a nonpolar plane as the main surface can be cut out.

In particular, when an orientation of the main surface is inclined from the nonpolar plane toward the c-plane direction by 0° to 45°, a main surface having a relatively small polarity can be obtained, which is preferable.

The c-plane, which is a polar plane, refers to, for example, the (0001) plane and the (000-1) plane, which is an opposite plane thereto. The c-plane in the nitride crystal of a group 13 element is a group 13 metal face or an N-face, and corresponds to a Ga-face or an N-face in gallium nitride (GaN), respectively. The c-plane, which is a polar plane, can be sliced to cut out the plate-like gallium nitride single crystal 7 having an N-face as one main surface and a Ga-face as the other main surface.

The plate-like single crystal 7 cut out in the slicing step may be machined into a desired outer shape by dicing, laser beam machining, or the like. The outer shape (planar shape) of the obtained single crystal 7 is not limited, and may be circular or polygonal. The dimensions are not limited as long as the obtained single crystal 7 is plate-like (relatively small in thickness with respect to the dimensions of the main surface).

This completes the preparation step S1.

### Back Surface Grinding Step S2

Subsequently, a back surface grinding step S2 illustrated in FIG. 1 is performed. The back surface grinding step S2 is performed mainly for machining to a desired thickness and controlling flatness and surface roughness of the back surface. Specifically, the back surface is preferably ground by, for example, lapping, grinding with a grindstone, or the like with the front surface of the single crystal 7 is attached to a base. Crystal defects, residual stress, and the like caused by grinding may be removed by etching. As the base, a single-crystal holder 2 to be used in the next step may be used.

### Front Surface Grinding Step S3

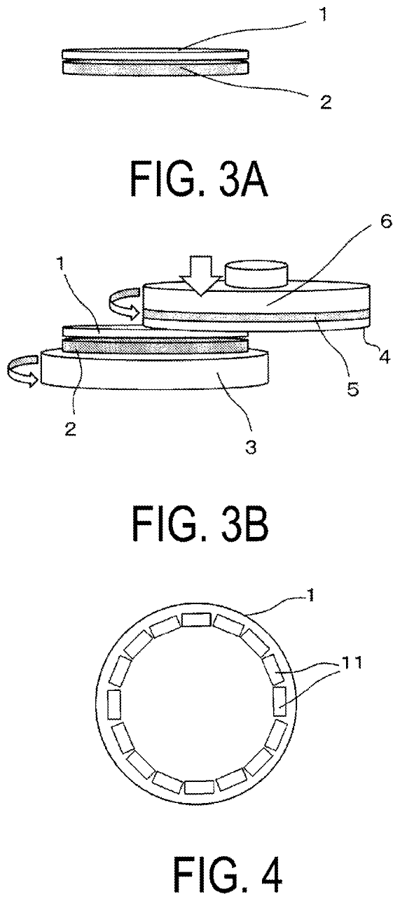

Subsequently, a front surface grinding step S3 is performed. The front surface grinding step S3 is illustrated in FIGS. 3A and 3B. As illustrated in FIGS. 3A and 3B, a vertical spindle rotary table type grinding machine was used in which a rotation axis of a chuck table 3 on which the single crystals 7 were placed was parallel to a rotation axis of a grindstone holder 5 that holds grindstones 4. First, as illustrated in FIG. 3A, the gallium nitride single crystals 7 are attached and held on a surface of the single-crystal holder 2 together with a carrier 1 (see FIG. 6). In order to increase productivity, a plate-shaped body having an area larger than that of the single crystals 7 is preferably used as the single-crystal holder 2, so that the multiple gallium nitride single crystals 7, for example, about three to ten odd gallium nitride single crystals 7 are held on the surface of the single-crystal holder 2.

The carrier 1 is a template to be attached to the single-crystal holder 2 together with the gallium nitride single crystals 7. The carrier 1 in the present embodiment is, for example, a plate-shaped body having a shape illustrated in FIG. 4, and is provided with multiple opening portions 11 for housing the gallium nitride single crystals 7. The opening portions 11 are recessed portions or through holes. An embodiment using the through hole type opening portions 11 will be described below.

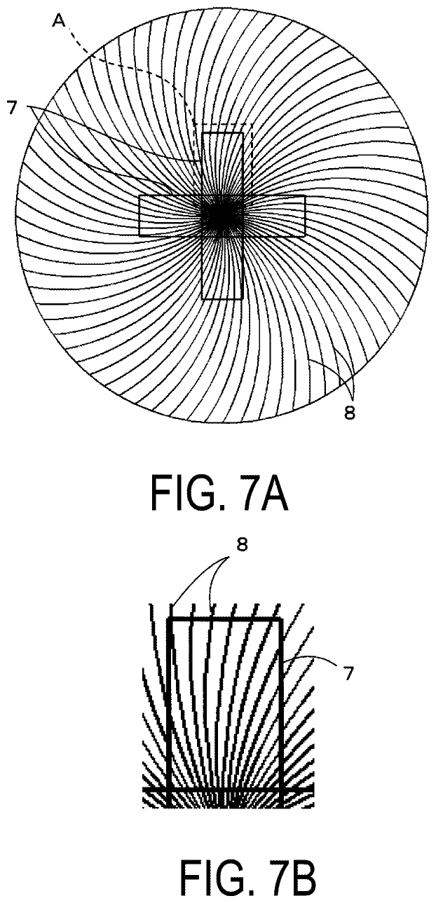

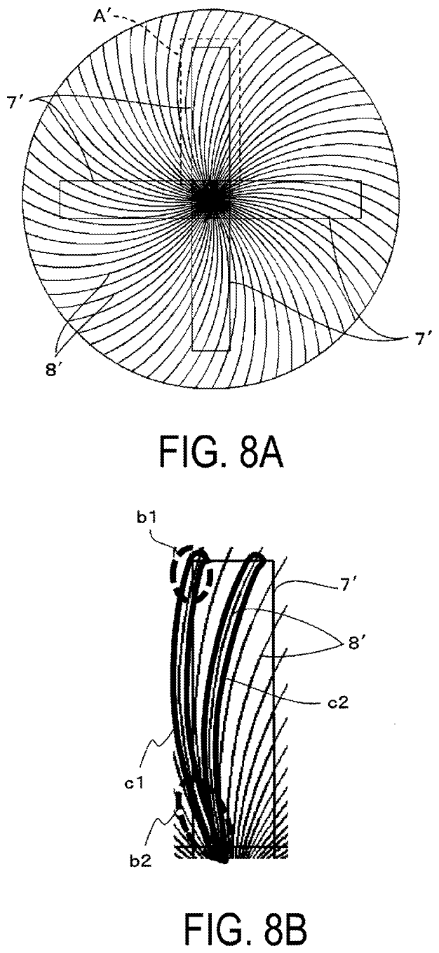

The carrier 1 illustrated in FIG. 3A is held on the surface of the single-crystal holder 2 with the gallium nitride single crystals 7 housed in the multiple opening portions 11. The multiple opening portions 11 are annularly arranged at a peripheral portion of the carrier 1 along a circumferential direction. Thus, the number of gallium nitride single crystals 7 that can be machined simultaneously can be increased, thereby improving productivity. The opening portions 11 may be arranged on multiple concentric circles. As illustrated in FIGS. 7B and 8B, within the surface of the single crystal 7, a difference in the grinding direction tends to be larger in a width direction (circumferential direction) on a side closer to the center of the carrier 1. When the opening portion 11 is provided near the center of the carrier 1, controlling the grinding direction by the grindstone 4 is difficult. Therefore, the opening portion 11 is particularly preferably spaced radially from the center of the carrier 1 by more than half the width of the opening portion 11 (i.e., one single crystal 7) (the dimension in the circumferential direction of the carrier 1, the long side direction of a rectangle in FIG. 6).

Since a grindstone track 8 has a curvature, the smaller the length of the opening portion 11 (the dimension in the radial direction of the carrier 1, the short side direction of the rectangle in FIG. 6) with respect to the diameter of the grindstone track 8, the easier it is to control the grinding direction of the grindstone 4 within the surface of the single crystal 7. For example, the width of the opening portion 11 may be equal to or less than half the diameter of the grindstone track 8.

The carrier 1 is made of carbon fiber reinforced plastic (CFRP). Since CFRP is excellent in strength, as will be described later, one carrier 1 can be used in both the grinding and CMP steps, avoiding the time and effort of reattaching the carrier 1 and reduction in flatness due to reattaching. In CFRP, carbon fiber is used as a reinforcing material, and a thermosetting epoxy resin is mainly used as a base material, but thermosetting resins such as an unsaturated polyester resin and a phenol resin, as well as thermoplastic resins such as polyamide (PA), polycarbonate (PC), polyphenylene sulfide (PPS), and polyether ether ketone (PEEK) may also be used.

Use of such a carrier 1 made of CFRP enables improved productivity and reduced manufacturing costs for the gallium nitride single-crystal substrates, as well as improved machining accuracy.

As the single-crystal holder 2, for example, a silicon substrate, an alumina (Al₂O₃) substrate, a sapphire (single-crystal alumina) substrate, and a silicon carbide (SiC) substrate can be used. In order to attach the carrier 1 with the gallium nitride single crystals 7 onto the single-crystal holder 2, for example, an adhesive such as wax or an epoxy adhesive, or double-sided tape (an adhesive tape having adhesive on both sides) may be used. The carrier 1 surrounding the gallium nitride single crystals 7 functions as a dummy to be ground together with the gallium nitride single crystals 7, thereby improving the machining accuracy of end portions of the gallium nitride single crystals 7.

Subsequently, as illustrated in FIG. 3B, the single-crystal holder 2 to which the gallium nitride single crystals 7 are attached is placed on the chuck table 3. The chuck table 3 has a surface with a porous structure, and holds the single-crystal holder 2 flat using negative pressure. The chuck table 3 is rotatable about a central axis thereof by a rotational drive source (not illustrated). Note that the carrier 1 holding the gallium nitride single crystals 7 may be directly held by the chuck table 3 without using the single-crystal holder 2.

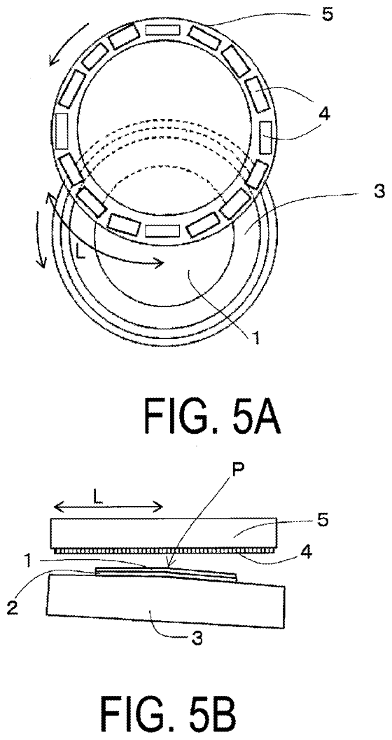

The grindstones 4 (see FIGS. 5A and 5B), which grind the gallium nitride single crystals 7, are, for example, rectangular and are held by a wheel-shaped grindstone holder 5. The arrangement of the grindstones 4 on the grindstone holder 5 is not limited, and multiple elongated grindstones 4 may be annularly arranged at equal distances in a circumferential direction of the grindstone holder 5, or may be radially arranged in a radial direction, or a disc-shaped or annular grindstone 4 may be used. In the embodiment in which the multiple grindstones 4 are arranged in a ring along the circumferential direction of the grindstone holder 5, the grindstones 4 each having an elongated shape having a major axis and a minor axis are arranged with the major axis in the circumferential direction and the minor axis in the radial direction. At this time, diameters (pitch circle diameters of the grindstones 4) of the tracks 8 and 8′ (see FIGS. 7A and 7B, and FIGS. 8A and 8B) of the grindstones 4 are larger than or equal to the width (diameter) of an area in which the single crystals 7 are arranged. The grindstones 4 may have curved shapes with curvatures corresponding to the tracks 8 and 8′. As the grindstone 4 to be used, for example, a diamond grindstone, a SiC grindstone, or the like can be used. Abrasive grains of the grindstone 4 are not limited as long as they can grind the gallium nitride single crystal 7; however, the grit of the grindstone 4 is preferably from #1000 to #5000. After grinding with a grindstone 4 having a low grit (from #1000 to #5000) with a relatively large grain size, grinding may be performed with a grindstone 4 having a high grit (e.g., #6000 or more) with a relatively small grain size.

As illustrated in FIG. 3B, the grindstone holder 5 is fixed to a tip end portion of a spindle 6, and rotation of the spindle 6 causes the grindstone holder 5 to rotate in the circumferential direction.

When the gallium nitride single crystals 7 are ground, the single-crystal holder 2 and the grindstone holder 5 are positioned to face each other (see FIGS. 3B and 5A). The gallium nitride single crystals 7 and the grindstones 4 are then rotated and pressed against each other at a predetermined pressure to grind the main surfaces of the gallium nitride single crystals 7. The carrier 1 houses and holds the gallium nitride single crystals 7 in the peripheral opening portions 11 illustrated in FIG. 4, and as illustrated in FIG. 5A, the positional relationship between the single-crystal holder 2 and the grindstone holder 5 is adjusted so that the grindstones 4 pass near the center of the carrier 1.

As illustrated in FIG. 5B, the chuck table 3 may be inclined with a center portion P as an apex. Thus, the carrier 1 and the single crystals 7 are deformed along the shape of the chuck table 3, and only part of the carrier 1 and the single crystals 7 is brought into contact with the grindstones 4, thereby limiting the grinding area. Thus, workability can be improved while reducing load applied to the machine and jigs, and in particular, control of the grinding direction of the single crystals 7 placed near the center of the carrier 1 is facilitated. In FIG. 5B, an arrow L indicates the grinding area.

As illustrated in FIGS. 3B and 5A, the single-crystal holder 2 and the grindstone holder 5 rotate in the same direction, but they may rotate in opposite directions. The number of revolutions of the chuck table 3 holding the single-crystal holder 2 is preferably from 50 rpm to 500 rpm. The number of revolutions of the grindstones 4 is preferably greater than the number of revolutions of the chuck table 3, and the rotational speed (peripheral speed) of the grindstones 4 is preferably from 10 m/sec to 50 m/sec. The feed rate of the grindstones 4 in the thickness direction of the single crystals 7 is preferably from 0.01 μm/s to 1.0 μm/s.

In the present embodiment, the multiple opening portions 11 for housing the gallium nitride single crystals are provided at the peripheral portion of the carrier 1 along the circumferential direction (see FIG. 4). This can increase productivity. In the grinding, by grinding the main surface of the single crystal 7 so as to protrude from the main surface of the carrier 1, wear of the carrier 1 can be reduced. In a case where the carrier 1 and the single crystal 7 are machined together, when the material of the carrier 1 is harder (harder to be ground) than the single crystal 7, machining time or machining load increases. Therefore, it is preferable to use the carrier 1 having hardness equal to or less (equal to or higher grinding rate) than that of the single crystal 7, with the main surface of the single crystal 7 protruding from the main surface of the carrier 1 during machining.

At this time, as schematically illustrated in FIG. 6, a gap G between the adjacent opening portions 11 is preferably equal to or less than a track width W of the grindstone 4. During grinding, there is usually a difference in thickness between the carrier 1 and the single crystal 7 (the single crystal 7 is thicker). In a case where the gap between the opening portions 11, that is, the gap G between the main surfaces of the single crystals 7 housed in these opening portions 11, respectively, is larger than the track width W of the grindstone 4, when the single crystal 7 deviates from the grindstone track 8 due to the rotation of the chuck table 3, the grindstone 4 may fall into the gap between the single crystals 7, and a side surface of the grindstone 4 may collide with a corner portion of the single crystal 7, causing the grindstone 4 or the single crystal 7 to chip. When the grindstone 4 is chipped during grinding, the single crystal 7 is likely to be scratched by the entrapped chips. Here, the gap G refers to the shortest distance between the opening portions 11. Note that when the material of the carrier 1 is too low in hardness (easier to be ground) than the single crystal 7, wear of the carrier 1 during grinding is large, resulting in a decrease in machining accuracy and an increase in manufacturing costs. Therefore, it is preferable that the hardness of the carrier 1 be equal to or slightly lower than the single crystal 7 (the grinding rate is equal to or slightly higher than that of the single crystal).

The track width W of the grindstone 4 varies depending on the size of the machine and the like, but is preferably, for example, about 1 mm to 30 mm.

When the number of revolutions of the grindstone 4 is higher than the number of revolutions of the chuck table 3, the track 8 of the grindstone 4 that passes within the main surface of the single crystal 7 during one rotation of the grindstone 4 is substantially arcuate. In the grinding step, it is preferable that the track 8 of the grindstone 4 continuously pass within the main surface of one single crystal 7 only once during one rotation of the grindstone 4. In other words, in the grinding step, the track 8 of the grindstone 4 that passes within the main surface of one single crystal 7 is preferably a continuous arc without deviating from the main surface of the single crystal 7. For example, in the example illustrated in FIGS. 7A and 7B, which is an enlarged view of a portion A in FIG. 7A, in the grindstone track 8, the grindstone 4 passes through only once for any single crystals 7.

On the other hand, in the example illustrated in FIGS. 8A and 8B, which is an enlarged view of a portion A′ in FIG. 8A, the grindstone track 8′ passes within the main surface of one single crystal 7′ in two portions (see a portion C1 of the grindstone track 8′). That is, it is two portions at a portion b1 and a portion b2 in FIG. 8B. Thus, when the single crystal 7′ is long from the center to the outer side, the grindstone track 8′ passes over the main surface of one single crystal 7′ in two portions. Therefore, the concentration of the surface pressure (machining load) of the grindstone 4 tends to cause thickness variation within the surface.

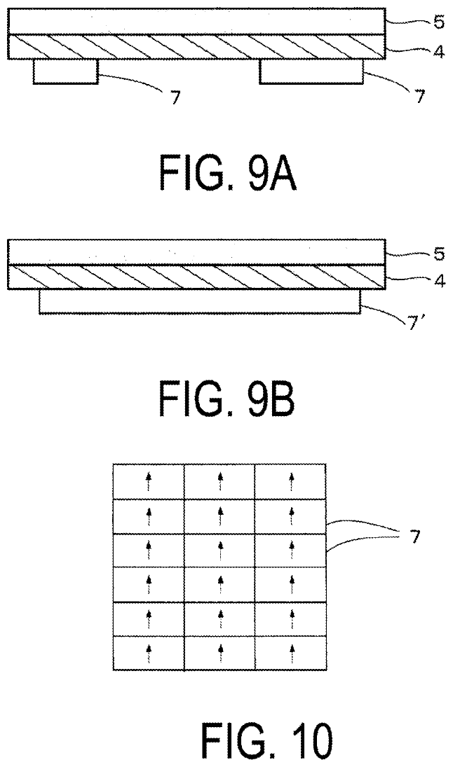

FIG. 9A is a schematic cross-sectional view of the portion C1 illustrating the grindstone track 8′ including the portion b1 and the portion b2 in FIG. 8B, and FIG. 9B is a schematic cross-sectional view of the portion C2 illustrating the grindstone track 8′ in FIG. 8B. As illustrated in FIG. 9A, when an area ratio occupied by the single crystal 7 in the grindstone 4 is low, the surface pressure applied to the single crystal 7 increases and grinding speed increases. On the other hand, as illustrated in FIG. 9B, when the area ratio occupied by the single crystal 7 in the grindstone 4 increases, the surface pressure applied to the single crystal 7 decreases and the grinding speed slows down. Therefore, when there are areas with a small occupied area ratio and a large surface pressure, such as the portion b1 and the portion b2 of the grindstone track 8′, the thickness variation within the surface is likely to occur.

In order to allow the track 8 of the grindstone 4 to pass within the main surface of one single crystal 7 only once, it is preferable to adjust the dimension of the single crystal 7 with respect to the curvature of the track of the grindstone 4, particularly the radial dimension of the single-crystal holder 2. For this purpose, it is preferable to shorten the single crystal 7 in the radial direction of the single-crystal holder 2.

In the grinding step of the gallium nitride single crystal 7 having a nonpolar plane or a semipolar plane as the main surface, workability differs depending on a direction (angle) of incidence of the grindstone 4, thereby changing the surface roughness. For example, as illustrated in FIG. 10, a description will be given of a case where 18 single crystals 7 having a semipolar plane are attached to the surface of the single-crystal holder 2. In FIG. 10, arrows indicate a direction of the direction (the direction of the gallium face) of the single crystal 7 projected onto the main surface. An upper side (the direction of the arrow) of each single crystal 7 is a side close to the gallium face, and a lower side is a side close to the N-face.

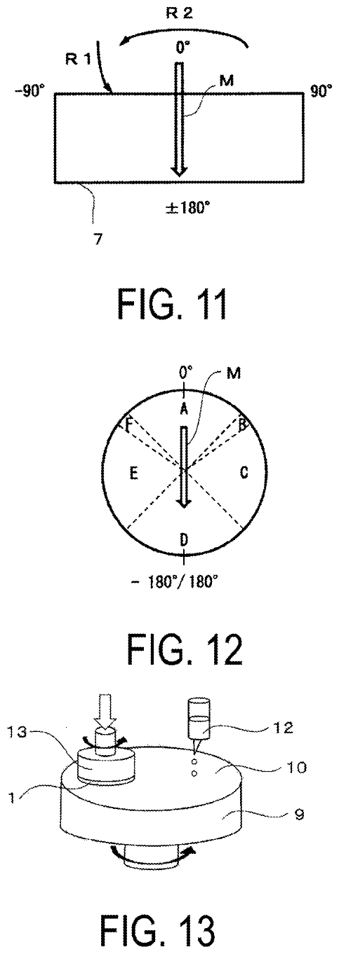

As illustrated in FIG. 11, the grinding direction of the grindstone 4 is represented by an angle between a direction M obtained by projecting the [000-1] direction of the single crystal 7 onto the main surface and a direction R1 in which the grindstone 4 grinds the main surface as the single-crystal holder 2 and the grindstone holder 5 rotate. In FIG. 11, the angles formed, in a rotation direction R2 of the gallium nitride single crystal 7, are 0° to 180° on an upstream side and 0° to −180° on a downstream side.

Under these conditions, when the (20-2-1) plane (the main surface on the [000-1] direction side) of the semipolar gallium nitride single crystal 7 having the (20-21) plane and the (20-2-1) plane as the main surfaces was ground, it was found that the surface roughness of the gallium nitride single crystal 7 varies depending on the angle between the direction in which the grindstone 4 grinds the main surface of the gallium nitride single crystal 7 and the direction in which the c-axis of the gallium nitride single crystal 7 is projected onto the main surface (the surface roughness varies depending on angle ranges). That is, when the surface roughness of each of the gallium nitride single crystals 7 after grinding was examined, it was found that the surface roughness was classified into the angle ranges A to F illustrated in FIG. 12 and the following Table 1. Each range is represented by an angle between a direction obtained by projecting the [000-1] direction of the gallium nitride single crystal 7 onto the main surface and a direction in which the grindstone 4 grinds the main surface. In the rotation direction of the single crystal 7, the upstream side is 0° to 180°, and the downstream side is 0° to −180°. The grinding direction of the grindstone 4 was determined from grinding marks (tracks of the grindstones 4) formed on the main surface.

Table 1 shows the surface roughness for each angle range after grinding.

TABLE 1

| | | Arithmetic mean | Thickness T |
|---|---|---|---|
| | Angle range | height Sa (nm) | (μm) |
| A | −45° to 0° to 45° | 385 | 1315 |
| B | More than 45° and less than 55° | 58 | 1316 |
| C | 55° to 135° | 229 | 1315 |
| D | More than 135° and | 14 | 1317 |
| | not more than 180° and | | |
| | not less than −180° and | | |
| | less than −135° | | |
| E | −135° to −55° | 216 | 1315 |
| F | More than −55° and | 51 | 1316 |
| | less than −45° | | |

Specific machining conditions under which the surface roughness (arithmetic mean height Sa) shown in Table 1 was obtained were as follows: the number of revolutions of the chuck table 3 was 100 rpm; the grindstone 4 was a #3000 diamond grindstone; the rotational speed (peripheral speed) of the grindstone 4 was 19 m/s; and the feed rate of the grindstone 4 was 0.12 μm/s or less.

The arithmetic mean height Sa can be obtained by, for example, a laser microscope (VK-X1100 manufactured by KEYENCE CORPORATION). For example, the measurement mode is color ultra-depth, the measurement magnification is 1200× (50× objective, 24× eyepiece), the measurement range is about 60 μm×80 μm, and the measurement pitch, the cutoff filter λs, and the cutoff filter λc are appropriately set in accordance with the surface shape of the measurement area, the arithmetic mean height Sa is measured at multiple points (five or more points), and the mean value is used as the measurement value. The thickness T of the single crystal 7 can be obtained with a micrometer.

As is apparent from Table 1, the arithmetic mean height Sa of the gallium nitride single crystal 7 is larger in the ranges A, C, and E than in the other ranges B, D, and F. That is, in the ranges B, D, and F, the main surface is close to a mirror surface, whereas in the ranges A, C, and E, the arithmetic mean height Sa is 0.2 μm or more, and the main surface is a so-called mat surface. It can also be seen that the thickness T of the gallium nitride single crystal 7 is smaller in the ranges A, C, and E than in the other ranges B, D, and F (the amount of grinding is larger when the single crystals 7 having substantially the same initial thickness are compared).

A surface ground by the #3000 grindstone 4 is generally a mat surface. In the ranges A, C, and E, the main surface of the single crystal 7 ground by the grindstone 4 has an arithmetic mean height (Sa) of 0.2 μm or more, which suggests that the grinding is properly performed. On the other hand, in the ranges B, D, and F, the main surface of the single crystal 7 ground by the grindstone 4 has an arithmetic mean height (Sa) of less than 0.2 μm, which suggests that the grinding is not properly performed (the polishing is performed despite using the grindstone for grinding). In these ranges, there is a concern that a relatively large residual stress is generated on the machined surface due to improper grinding. In the ranges A, C, and E, the surface state of the machined surface is all relatively uniform. In the present disclosure, the grinding marks on the main surface of the single crystal 7 are formed by multiple arcs, and the grinding direction of the grindstone 4 changes within the main surface of the single crystal 7. In such a case, it is preferable that, in all areas of the main surface, the grinding directions of the grindstone 4 (i.e., all grinding marks) be in the range A, C, or F, but it is preferable that the grinding directions of the grindstone 4 be in the range A, C, or F in at least half of the main surface (i.e., half or more of the grinding marks).

In particular, in the range A, the arithmetic mean height Sa is larger than in the other ranges. In the range A, the surface state of the machined surface is particularly uniform as compared with the other ranges. Therefore, it is preferable to perform grinding so that the grinding direction of the grindstone 4 is within the range A.

After the grinding is completed, the single-crystal holder 2 is removed from the chuck table 3.

### CMP Step S4

Subsequently, the process proceeds to a CMP step S4. The CMP step S4 is illustrated in FIG. 13. CMP is machining for polishing (mirror-polishing) the surface and eliminating fine surface distortion.

FIG. 13 illustrates a configuration of a chemical mechanical polisher (CMP). In this machine, a polishing pad 10 is provided on a surface of a rotating surface plate 9, and a slurry 12 that is alkaline and that contains abrasive grains is supplied onto the polishing pad 10. The carrier 1 housing the gallium nitride single crystals 7 and the single-crystal holder 2 are held on a lower surface of a support 13 after being removed from the chuck table 3 of the grinding machine. In this state, the support 13 is pressed against the polishing pad 10 while being rotated. This causes the single crystals 7 to be easily polished by a chemical reaction caused by the slurry 12, and the single crystals 7 are further mechanically polished by the surface of the polishing pad 10.

Examples of the abrasive grains include silica, ceria, titania, zirconia, and alumina. Examples of the components of the alkaline slurry 12 other than the abrasive grains include an aqueous sodium hydroxide solution and an aqueous potassium hydroxide solution. A pH of the slurry 12 is preferably adjusted from 8 to 14.

In FIG. 13, a rotation direction of the polishing pad 10 and a rotation direction of the support 13 are the same, but may be opposite directions. The slurry 12 may be dropped continuously or intermittently during the polishing step.

Carbon fiber reinforced plastic (CFRP), which is a material of the carrier 1, has a high polishing resistance to the slurry 12 that is alkaline. Therefore, the carrier 1 is hardly polished during the CMP, and the thickness change is small. On the other hand, when the carrier 1 containing silicon (Si), for example, the carrier 1 made of glass fiber reinforced plastic (GFRP), is subjected to the CMP using the slurry 12 that is alkaline, the difference in thickness between the carrier 1 and the single crystals 7 increases.

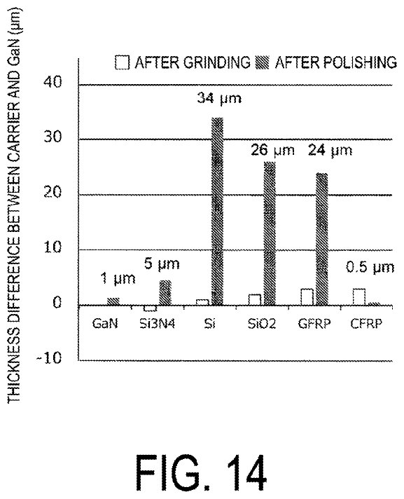

FIG. 14 is a graph showing the thickness difference between the carrier 1 and the single crystal 7 after being ground in the front surface grinding step (S3) in which the carrier 1 and the single crystal 7 were ground together and after being polished in the CMP step (S4) in which the carrier 1 and the single crystal 7 were polished together using the alkaline slurry 12 for various carrier materials.

As a result, CFRP showed a small thickness difference of 0.5 μm particularly in the CMP step. CFRP also showed a small thickness variation both after grinding and polishing.

By the carrier 1 being made of GaN, Si, SiO₂, GFRP, or CFRP, the thickness difference between the single crystal 7 and the carrier 1 after the co-grinding step can be from 0 μm to 3 μm (the grinding rate is equal to or slightly larger than that of the single crystal 7). In particular, by the carrier 1 being made of CFRP, the thickness difference between the single crystal 7 and the carrier 1 after the CMP step (after polishing) can be from −1 μm to 1 μm (i.e., the polishing rates of the carrier 1 and the single crystal 7 are substantially the same). Using the carrier 1 made of a material that makes a thickness difference after the co-polishing larger than 1 μm (easier to be polished than the single crystal 7) causes a decrease in machining accuracy and an increase in manufacturing costs due to a decrease in the number of times the carrier 1 can be used. Using the carrier 1 with a thickness difference after the co-polishing of less than-1 μm (harder to be polished than the single crystal 7) causes a decrease in machining accuracy and a decrease in machining rate. Therefore, when the carrier 1 is made of a material that makes a thickness difference after the co-polishing from −1 μm to 1 μm, the carrier 1 can be machined with a high accuracy and at a low cost. In particular, when the thickness difference after the co-polishing is 0 μm or more, a relatively high polishing rate can be obtained.

Note that the use of the carrier 1 of the present embodiment is not limited to co-polishing. When the thickness of the single crystal 7 before polishing is made to be larger than that of the carrier 1 and the main surface of the single crystal 7 is machined while the main surface of the single crystal 7 is made to protrude from the main surface of the carrier 1, wear of the carrier 1 can be reduced, the number of times the carrier 1 can be used can be increased, and the manufacturing costs can be reduced.

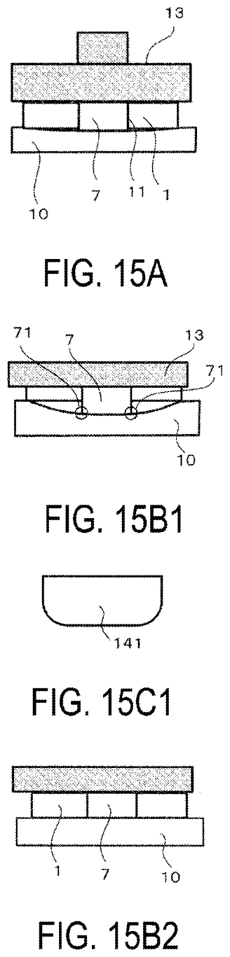

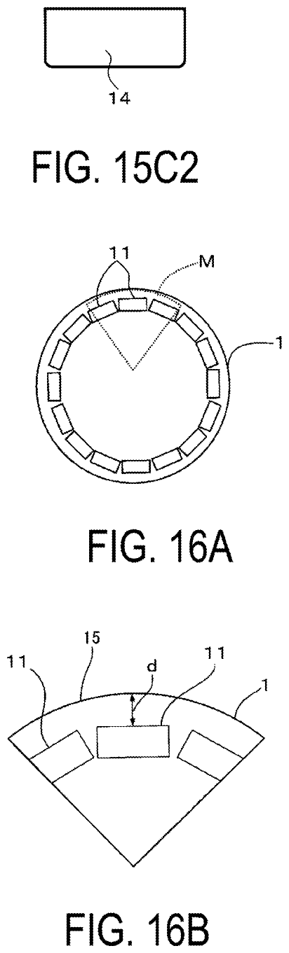

When the difference between the polishing rate of the carrier 1 and the polishing rate of the single crystal 7 is large, a step is formed between the polished surface of the single crystal 7 and the carrier 1, which causes a decrease in machining accuracy. The carrier 1 made of CFRP has a small difference in polishing rate from the single crystal 7 when the slurry 12 that is alkaline is used. Therefore, surface sagging of the single crystal 7 during polishing can be suppressed and flatness can be improved. FIG. 15 is an explanatory diagram for explaining surface sagging of the single crystal 7 during polishing in the CMP step.

As illustrated in FIG. 15A, the carrier 1 housing the single crystal 7 in the opening portion 11 is pressed against the polishing pad 10 by the support 13, and polished while being rotated. At this time, when the carrier 1 is made of a material such as Si that is easily polished, a thickness difference occurs between the carrier 1′ and the single crystal 7 as illustrated in FIG. 15B1. As a result, pressure tends to concentrate on end portions 71 of the single crystal 7. Therefore, a single-crystal substrate 141 obtained by polishing the single crystal 7 is subjected to a large amount of polishing at the end portions 71, as illustrated in FIG. 15C1, that is, so-called surface sagging occurs, resulting in increased thickness variation.

On the other hand, when the carrier 1 is made of CFRP, there is almost no thickness difference between the carrier 1 and the single crystal 7. Therefore, as illustrated in FIG. 15B2, pressure is distributed over an entire single crystal 7, and the single crystal substrate 14 obtained by polishing maintains flatness even at the end portions 71, as illustrated in FIG. 15C2.

Thus, when the carrier 1 is made of CFRP, the carrier 1 can be repeatedly used, which has an advantage of reducing manufacturing costs.

As illustrated in FIG. 16A and FIG. 16B, which is an enlarged view of a portion M in FIG. 16A, the opening portions 11 provided in the carrier 1 preferably have a distance d of 2 mm or more from an outer edge 15 of the carrier 1. By separating the opening portions 11 from the outer edge 15 of the carrier 1 by 2 mm or more as described above, pressure is distributed by the carrier 1 even at the end portions 71 close to the outer edge of the carrier 1, thereby suppressing surface sagging at the end portions 71. Thus, as illustrated in FIGS. 15B2 and 15C2, the pressure is distributed over the entirety of the single crystal 7, and the flatness of the end portions 71 of the single-crystal substrate 14 obtained by polishing can be maintained.

Note that the carrier 1 usually has a disk shape having a diameter from 50 mm to 300 mm, but the carrier 1 is not limited to having a disc shape, and may have a polygonal shape such as a square.

As described in detail above, according to the present embodiment, the same carrier 1 can be used from the grinding step to the CMP step by using CFRP as the material of the carrier 1, which has a grinding speed close to that of the substrate material (the nitride crystal of a group 13 element) and is resistant to the alkaline slurry of CMP. Therefore, productivity and machining accuracy can be improved, and manufacturing costs can be reduced.

The embodiment of the present disclosure has been described above, but the present disclosure is not limited thereto, and various changes and improvements can be made within the range set forth in the present disclosure.

### REFERENCE SIGNS

1, 1′ Carrier
11 Opening portion
15 Outer edge
2 Single-crystal holder
3 Chuck table
4 Grindstone
5 Grindstone holder
6 Spindle
7 Single crystal (nitride crystal of group 13 element in periodic table)
71 End portion
8 Grindstone track
9 Surface plate
10 Polishing pad
11 Opening portion
12 Alkaline slurry
13 Support
14, 141 Single-crystal substrate (substrate of nitride crystal of group 13 element in periodic table)

1. A manufacturing method for manufacturing a substrate of a crystal of a nitride of a group 13 element in the periodic table, the manufacturing method comprising:
grinding main surfaces of crystals of a nitride of a group 13 element in the periodic table with a grindstone rotating while housing the crystals in multiple opening portions provided in a carrier and rotating the crystals, each of the main surfaces being a semipolar plane or a nonpolar plane, and the carrier being made of carbon fiber reinforced plastic; and
chemical mechanical polishing the main surfaces after grinding while the crystal is housed in the carrier, a slurry used in the chemical mechanical polishing being alkaline.

2. The manufacturing method according to claim 1, wherein the substrate of the crystals of the nitride of a group 13 element in the periodic table is a gallium nitride single-crystal substrate.

3. The manufacturing method according to claim 1, wherein the multiple opening portions are provided at a peripheral portion of the carrier along a circumferential direction.

4. The manufacturing method according to claim 3, wherein a gap between the main surfaces of the crystals adjacent to one another housed in the multiple opening portions is equal to or less than a track width of the grindstone.

5. The manufacturing method according to claim 1, wherein in the grinding, a track of the grindstone passes within one of the main surfaces of the crystals only once during one rotation of the grindstone.

6. The manufacturing method according to claim 1, wherein the multiple opening portions are separated from an outer edge of the carrier by 2 mm or more.

7. The manufacturing method according to claim 1, wherein a thickness difference between the crystal and the carrier after the grinding (a single-crystal thickness−a carrier thickness) is 0 μm or more.

8. The manufacturing method according to claim 1, wherein a thickness difference between the crystal and the carrier after the grinding (a crystal thickness−a carrier thickness) is from 0 μm to 3 μm.

9. The manufacturing method according to claim 1, wherein a thickness difference between the crystal and the carrier after the chemical mechanical polishing is from −1 μm to 1 μm.
